(19) United States
(12) Patent Application Publication
(10) Pub. No.: US 2023/0328928 A1
(43) Pub. Date: Oct. 12, 2023

(54) METAL AND GRAPHITE OVER FOAM FOR PLACEMENT BETWEEN COMPONENTS IN ELECTRONIC DEVICES

(71) Applicant: META PLATFORMS TECHNOLOGIES, LLC, Menlo Park, CA (US)

(72) Inventors: Eric Mun Khai Leong, Kirkland, WA (US); Adam Richard Weber, Sammamish, WA (US)

(21) Appl. No.: 17/714,792

(22) Filed: Apr. 6, 2022

(51) Int. Cl. H05K 7/20; G06F 1/20; G06F 1/16

(52) U.S. Cl. CPC H05K 7/2039; G06F 1/206; H05K 7/20336; G06F 1/163; H01L 23/3735

(57) ABSTRACT

Embodiments relate to a compressible conductive foam having high heat conductivity and high electrical conductivity by having a graphite layer surround a core material, and having a metal layer surround the graphite layer. The metal layer may be a metal sheet or a metal fabric including copper. The metal layer increases the electrical conductivity of the compressible conductive foam while retaining the high thermal conductivity due to the graphite layer.

### BACKGROUND

The present disclosure relates to an electrical and thermal conductive foam, and specifically to a conductive foam with a graphite layer and a metal layer.

Electronic devices often include components that generate heat. These components may be connected to a heat sink, frames or other components to dissipate the heat. Some of these components are electrically grounded to the same heat sink, frames or other components so as not to interfere with antennas. Hence, a conductive form is often placed between these components to promote transfer of heat and conducting of electricity between the components. These foams generally include a resilient material and is wrapped around with a film to increase the contact between the components. Depending on the film and the resilient materials of these foams, these foams have relatively heat conductivity but lower electrical conductivity or vice versa, but not both.

### SUMMARY

Embodiments relate to a conductive compressible foam with both high heat conductivity and high electrical conductivity. The foam includes a core material that is compressible, a graphite layer that extends over a periphery of the core material, and a metal layer on the graphite layer for contacting a first component and a second component of an electronic device.

In one or more embodiments, the foam further includes a first adhesive layer on a portion of the metal layer for securing the conductive foam to the first component, and a second adhesive layer on another portion of the metal layer for securing the conductive foam to the second component.

In one or more embodiments, the first adhesive layer and the second adhesive are pressure activated.

In one or more embodiments, the metal layer wraps around the core material and edges of the metal layer partially overlap, and the second adhesive layer spans across the overlapping edges of the metal layer.

In one or more embodiments, the metal layer is made of copper.

In one or more embodiments, the metal layer is a metal sheet or a metal-infused fabric.

In one or more embodiments, the core material is made of polyurethane.

### BRIEF DESCRIPTION OF DRAWINGS

Figure (FIG. 1 is a perspective view of a head-mounted display (HMD) according to one embodiment.

FIG. 2 is a perspective view of the HMD of FIG. 1 with a front cover removed, according to one embodiment.

FIG. 3 is an exploded view of components of the HMD of FIG. 1, according to one embodiment.

FIG. 4 is a cross-sectional view of a conductive compressible foam taken along line A-A′ of FIG. 3, according to one embodiment.

### DETAILED DESCRIPTION

In the following description of embodiments, numerous specific details are set forth in order to provide more thorough understanding. However, note that the embodiments may be practiced without one or more of these specific details. In other instances, well-known features have not been described in detail to avoid unnecessarily complicating the description.

Embodiments are described herein with reference to the figures where like reference numbers indicate identical or functionally similar elements. Also in the figures, the left most digit of each reference number corresponds to the figure in which the reference number is first used.

Embodiments relate to a compressible conductive foam having high heat conductivity and high electrical conductivity by having a graphite layer surround a core material, and having a metal layer surround the graphite layer. The metal layer may be a metal sheet or a metal-infused fabric including copper. The graphite layer provides high thermal conductivity while the metal layer provides high electrical conductivity. The metal layer may be copper in the form of a metal sheet or metal-infused fabric.

FIG. 1 is a perspective view of a head-mount display (HMD) 100 according to one embodiment. The HMD 100 may include, among other components, cameras 101, a front cover 103, a head strap connector 105, a side cover 107, and a head strap assembly. The head strap assembly may include a rear strap 109, and an upper strap 111 connected to the rear strap 109. The front cover 103 is attached at the front of the side cover 107. The head strap 109 is attached to the side cover 107 via the head strap connector 105. The upper strap 111 is attached to the head strap 109 and secured by inserting the end of the upper strap 111 into a slot formed in the side body. The front cover 103 covers a front side of the side cover 107. The components and the structure of HMD 100 as illustrated in FIG. 1 are merely illustrative.

The front cover 103 is a rigid member placed at the front part of the HMD 100 to protect components in the HMD 100. In one embodiment, the front cover 103 is secured to the side cover 107 via screws or other fastening mechanism that enables the front cover 103 to be removed from the side cover 107 for maintenance purposes. The front cover has two cameras 101 at upper two corners and bottom two edges. These cameras 101 can be used to capture views outside of the HMD 100, and display them to the user.

The head strap 109 and upper strap 111 wrap around a user's head to fasten the HMD 100 to the user's face. The head strap 109 and the upper strap 111 may be made of elastic, fabric or a combination thereof to be flexible yet comfortable for the user. The head strap 109 is connected to the side cover 107 of the HMD 100 by the head strap connector 105 which can rotate in relation to the side cover 107. Additionally, the head strap connector 105 can disconnect from the side cover 107, enabling a user to replace the head strap 109 or a maintenance technician easier access to the side cover 107. The upper strap 111 provides additional support and is connected to the head strap 109 and the top of the side cover 107.

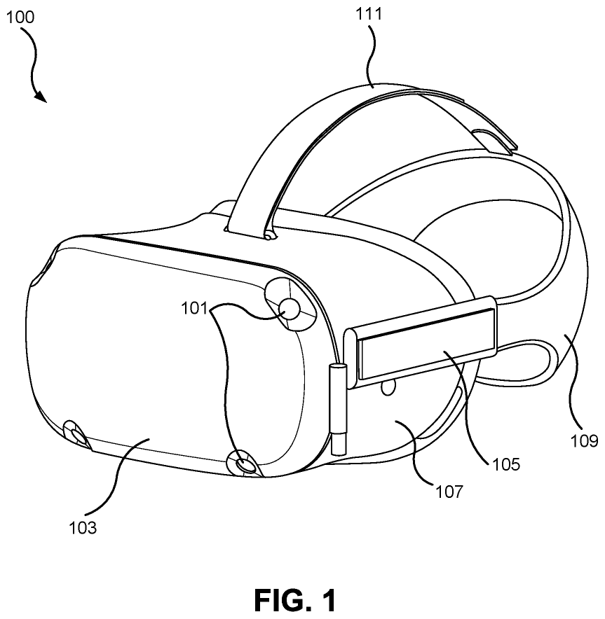

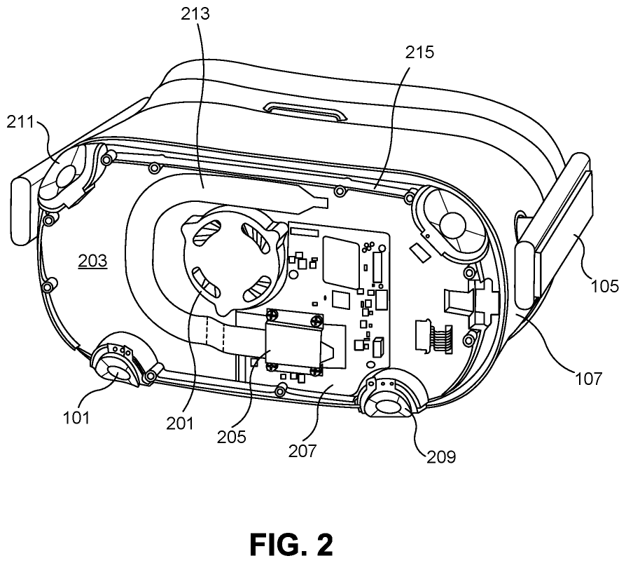

FIG. 2 is a perspective view of a HMD 100 with the front cover 103, head strap 109, and upper strap 111 removed, according to one embodiment. Behind the font cover 103, a fan 201, printed circuit board (PCB) 207, and heat pipe 213 are mounted to a front surface 203 of a metal frame 215. The HMD 100 also includes, a PCB bracket 205, lower brackets 209, and upper brackets 211. The PCB bracket 205 is mounted to the PCB 207 with an end of the heat pipe 213 placed between the PCB bracket 205 and the PCB 207. The lower brackets 209 and upper brackets 211 are mounted to the upper two corners and bottom two edges of the metal frame 215. The fan 201, heat pipe 213, and PCB 207 may be mounted to the metal frame 215 via screws or adhesive.

The fan 201 and heat pipe 213 dissipates heat generated by the PCB 207. The fan 201 also pulls air from the rear side of the HMD 100 where the user's face is located and thereby cools the user's face by circulating the air. The fan 201 is received in a hole formed in the metal frame 215.

The PCB bracket 205 is connected to the PCB 207 by screws and prevents the heat pipe from disconnecting from the PCB 207 due to thermal expansion, movement of the HMD 100, or application of an external force. The PCB bracket 205 also presses the end of the heat pipe 213 to a processor (not shown) mounted on the PCB 207 so that the heat generated by the processor can be transferred effectively.

The lower brackets 209 and upper brackets 211 surround at least a portion of the cameras 101 and protects the cameras 101 from external impact. For this purpose, the cameras 101 are located in concaved top surfaces of the brackets 209, 211. In this way, any external impact is likely to be applied to the brackets 209, 211 instead of the cameras 101. The brackets 209, 211 may be secured to the front surface 203 by screws that can be removed for easy access to the cameras 101.

The heat pipe 213 has an end connected to the processor of the PCB 207 while other parts are connected to the front surface 203 of the metal frame 215. The heat pipe 213 transfers heat to the metal frame 215 that functions as a heat sink for absorbing and dissipating the heat.

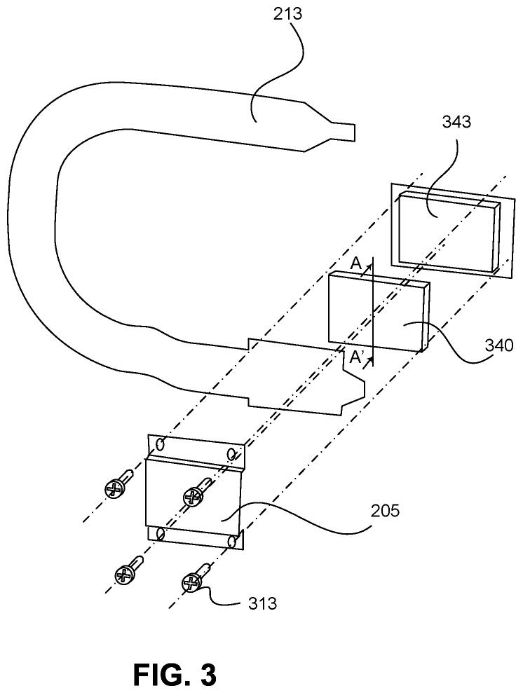

FIG. 3 is an exploded view of components of the HMD 100 of FIG. 1, according to one embodiment. A central processing unit (CPU) of the HMD 100 is secured to the PCB 207 via the PCB bracket 205 and screws 313. Between the CPU 343 and the PCT bracket 205, the heat pipe 213 and a compressible conductive foam 340 are placed. The compressible conductive foam 340 enhances transfer of heat and conducting of electricity from the CPU 343 to the heat pipe 213.

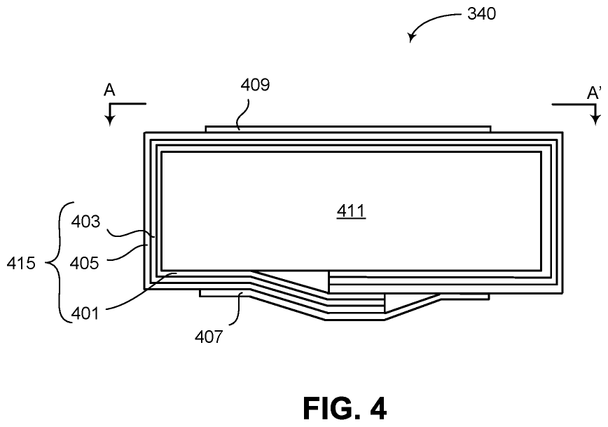

FIG. 4 is a cross-sectional view of the conductive compressible foam 340 taken along line A-A′ of FIG. 3, according to one embodiment. The conductive compressible foam 340 includes a compressible core material 411 and a wrapping film 415 that wraps around the core material 411. The conductive compressible foam 340 may include additional films or layers in addition to what are illustrated in FIG. 4.

The compressible core material 411 may be made of resilient material such as polyurethane foam. The thickness, width and height of the compressible core material 411 may be designed in line with the components between which the conductive compressible foam 340 is being placed.

A top adhesive layer 409 and a bottom adhesive layer 407 may be placed on the top and bottom surfaces of the conductive compressible foam 340 so that the conductive compressible foam 340 may be secured to the CPU 343 and the heat pipe 213. The top adhesive layer 409 and the bottom adhesive layer 407 may be pressure-sensitive adhesive (PSA). The bottom adhesive layer 407 also helps secure the edges of the wrapping film 415 so that the wrapping film 415 does not unwrap from the compressible core material 411.

The wrapping film 415 may include multiple layers. In one or more embodiments, the wrapping film includes an inner adhesive layer 401, a graphite layer 403 outside the inner adhesive layer 401 and a metal layer 405 on top of the graphite layer 403. The graphite has good thermal conductivity (thermal conductivity coefficient of 25-470 W/mk) but relatively poor electrical conductivity (electrical conductivity coefficient of 2×10⁵ to 3×10⁵ S/m).

Therefore, to increase the electrical conductivity, a metal layer is deposited on the graphite layer 403. The metal layer may be in the form of a metal sheet or a metal-infused fabric. In one or more embodiment, a copper sheet of a copper fabric is used. The copper has electrical conductivity of 5.96×10⁷ S/m that is higher than that of the graphite and has thermal conductivity coefficient of around 386 W/mK. Therefore, by adding the copper layer as the metal layer 405 on the graphite layer 403, the electrical conductivity of the conductive compressible foam 340 may be enhanced. In other embodiments, silver or an allow of silver and copper may be used as the metal layer.

In one or more embodiments, the wrapping film 415 wraps around the core material 411 and edges of the wrapping film 415 partially overlap. The bottom adhesive layer 407 spans across the overlapping edges of the wrapping film 415.

The inner adhesive layer 401 secures the gapping film 415 to the core material 411 and prevents separation of the wrapping film 415 from the core material 411. In one or more embodiment, the inner adhesive layer 401 is pressure activated. Instead of using the inner adhesive layer 401, other securing mechanisms such a staplers may be used to secure the wrapping film 415 to the core material 411.

In one or more embodiments, the thickness of the top adhesive layer 409 is thicker than the thickness of the metal layer 405, and the thickness of the bottom adhesive layer 407 is thicker than the thickness of the metal layer 405.

In one or more embodiments, the thickness of the graphite layer 403 is substantially the same as a thickness of the metal layer 405. The thickness of these layers may each be around 0.025 mm.

Although above embodiments were described with the conductive compressible foam having a rectangular prism shape, these are merely illustrative. The conductive compressible foam may have various shapes depending on the electrical components that are being connected via the conductive compressible foam. Moreover, the cross-sectional shape of the conductive compressible foam may have shapes other than square.

The foregoing description of the embodiments of the disclosure has been presented for the purpose of illustration; it is not intended to be exhaustive or to limit the disclosure to the precise forms disclosed. Persons skilled in the relevant art can appreciate that many modifications and variations are possible in light of the above disclosure.

What is claimed is:

1. A conductive compressible foam, comprising:
a core material that is compressible;
a graphite layer extending over a periphery of the core material; and
a metal layer on the graphite layer for contacting a first component and a second component of an electronic device.

2. The foam of claim 1, further comprising:
a first adhesive layer on a portion of the metal layer for securing the conductive foam to the first component; and
a second adhesive layer on another portion of the metal layer for securing the conductive foam to the second component.

3. The foam of claim 2, wherein the first adhesive layer and the second adhesive are pressure activated.

4. The foam of claim 2, wherein the metal layer wrap around the core material and edges of the metal layer partially overlap, and the second adhesive layer spans across the overlapping edges of the metal layer.

5. The foam of claim 1, wherein the metal layer is made of copper.

6. The foam of claim 1, wherein the metal layer is a metal sheet or a metal-infused fabric.

7. The foam of claim 1, wherein the core material is made of polyurethane.

8. An electronic device comprising
a first component;
a second components separate from the first component; and
a conductive compressible foam between the first component and the second components, the conductive compressible foam comprising:
a core material that is compressible,
a graphite layer extending over a periphery of the core material, and
a metal layer on the graphite layer for contacting the first component and the second component.

9. The electronic device of claim 8, wherein the first component generates heat and the second component dissipates the generated heat transferred from the first component via the conductive compressible foam.

10. The electronic device of claim 8, wherein the compressible conductive foam further comprises:
a first adhesive layer on a portion of the metal layer for securing the conductive foam to the first component; and
a second adhesive layer on another portion of the metal layer for securing the conductive foam to the second component.

11. The electronic device of claim 10, wherein the first adhesive layer and the second adhesive are pressure activated.

12. The electronic device of claim 10, wherein the metal layer wrap around the core material and edges of the metal layer partially overlap, and the second adhesive layer spans across the overlapping edges of the metal layer.

13. The electronic device of claim 8, wherein the metal layer is made of copper.

14. The electronic device of claim 8, wherein the metal layer is a metal sheet or a metal-infused fabric.

15. The electronic device of claim 8, wherein the core material is made of polyurethane.
